(19) United States
(12) Patent Application Publication
(10) Pub. No.: US 2006/0265511 A1
(43) Pub. Date: Nov. 23, 2006

(54) Apparatus and method for efficiently and securely transferring files over a communications network

(76) Inventors: Nicholas Dale Riggs, Leeds, AL (US); David Allen Sanders JR., Kimberly, AL (US); Michael Douglas Rhodes, Alabaster, AL (US)

Correspondence Address: SIROTE & PERMUTT, P.C., P.O. BOX 55727, 2311 HIGHLAND AVENUE SOUTH, BIRMINGHAM, AL, 35255-5727, US

(21) Appl. No.: 11/133,957

(22) Filed: May 20, 2005

(51) Int. Cl. G06F 15/16; H03M 7/00

(52) U.S. Cl. 709/231; 341/50

(57) ABSTRACT

A system and method to reduce the time to transfer files from one computer to another over a communications network, such as the Internet, by avoiding the synchronous timing limitations of current transfer methods. A file that is intended to be transferred from a transmitting computer to a receiving computer is partitioned into multiple synchronous block portions of the existing file, prior to transfer. Each block subportion of original file is compressed and queued for transmission to a target receiving computer. The compressed blocks are kept in a cue, encrypted, and transmitted asynchronously to a target receiving computer over a selected communications network. Upon receipt at the receiving computer of any of the transmitted blocks, blocks are decrypted, decompressed, and asynchronously reconstructed into the original file. Since the transmission of blocks to the receiving computer occurs asynchronously, as well as the transmission preparation steps, overall transmission times are improved.

This application claims the benefit of filing priority under 35 U.S.C. §119 and 37 C.F.R. §1.78 of the co-pending U.S. Non-Provisional application Ser. No. 10/434,824 filed May 9, 2003, for an Apparatus and Method for Efficiently and Securely Transferring Files Over a Communications Network which depends from Provisional Application No. 60/460,443 filed Apr. 4, 2003, having the same title. All information disclosed in those prior applications is incorporated herein by reference.

### FIELD OF THE INVENTION

The present invention relates generally to file transfer systems for transferring files from one computer to another. In greater particularity, the present invention relates to systems and methods for transferring compressed and encrypted files over long distance communications conduits. In even greater particularity, the present invention relates to file compression and encryption methods for transferring segmented files over a communications network.

### BACKGROUND OF THE INVENTION

The transferring of large data files over communications networks has always been the bane of network operators. Large files must be routinely transferred over a communications network to support the performance of various networked or server based applications. For example, various large databases must routinely be accessed and manipulated in corporate environments to keep track of business performance, and large files must repeatedly be accessed and saved while using accounting and database software, such as Oracle or associated custom SQL server applications. Similarly, design and manufacturing files, such as structural layout files for semiconductor chip or automobile designs, are typically accessed over network storage systems that, in some cases, may be remote from the actual CPU processing the data, or may even be accessed via a wide area network in which modulation and demodulation of data signals must occur during the transfer of the data from one point to another. Memory system topologies, such as RAID and the logical scaling of drives across virtual networks, as is currently employed by most medium and large size business organizations, exasperates the file transfer difficulty by physically locating large and complex files on memory subsystems having reduced access speeds. Hence, while processor speed has continued to exponentially increased over the last ten years in computing platforms, the accessibility of large data files has not kept pace with the processing speed potential and has become a substantial processor limitation.

The advent of the Internet has made more noticeable the file transfer delay limitation. While the Internet has dramatically increased the potential acquisition and processing of data, especially with the advent of reliable point-to-point data communications applications, limitations in access speeds to desired data has hindered the full growth potential of the Internet communication structure. One example in which this limitation becomes apparent is when a consumer attempts to rent and download a selected set of movies over the Internet for viewing at a time of their own choosing. While many legally licensed entities exists to provide access to movies for downloading and viewing, the download time for any selected movie can take longer than the time for the consumer to simply drive to a movie rental location and rent a DVD or VHS tape movie (e.g. nominal download times can be as much as six hours over a broadband cable modem connection to the Internet). Hence, while a great potential exists for the selection and leasing of movies over the Internet, the large download times required to obtain any selected movie makes the transaction prohibitive.

Current Internet communication protocols do not address this data communications limitation. For example, while the protocols of TCP/IP, TELNET, FTP, and HTTP, all provide robust error correcting and reliable packet switching mechanisms for transferring data from one point to another, they do not include inherent strategies for reducing the transmission time of large files transmitted across a network. As shown in FIG. 1, currently the most efficient method for transferring a relatively large file from one point to another over the Internet includes the procedures 10 of first compressing a file 11, transmitting the compressed file from one transmitting computer to a receiving computer 12, and decompressing the file 13 at the receiving computer location. As is known, file transmission time 14-16 may be significantly reduced by transferring a compressed file versus an uncompressed file over a communications network, such as the Internet. Obviously, this compress-transfer-decompress procedure would result in no transmission gains at all unless the file selected for transfer would be reasonably susceptible to compression. Fortunately, most data files are susceptible to significant compression ratios, thereby capitalizing on the increased processing power available on today's computing platforms and allowing for reduced transfer times of data files. As is seen in the figure, the total time 17 for transmitting a file from one computer to another is still limited by the amount of time required to compress a file 14 and decompress the file 16-17 at the transmitting and receiving locations. Further, file transmission times 14-16 are highly dependent on the type of Internet access a particular computer supports and, hence, can be highly dependent upon the state of a particular transmission environment between one computer and another. Therefore, while improvements in file compression speed, file transmission speed, and file decompression speed, will progress over time as processing speed increases and transmission conduits improve, the overall structure and limitations of each phase of transmitting a file from one point to another will remain the same. Moreover, the time associated with this file transmission structure will continue to lag behind increases in microprocessor speeds, thereby negating somewhat the advances in microprocessor design.

Therefore, what is needed is a novel system and method for avoiding the above described limitations of transferring a data file from one point to another over a communications network, such as the Internet.

### SUMMARY OF THE INVENTION

In summary, the present system and method provides an improved method for transferring files from one computer to another over a communications network, such as the Internet, without the synchronous timing limitations of nominal transfer methods. Prior to transfer, a file that is intended to be transferred from a transmitting computer to a receiving computer is partitioned into multiple synchronous block portions replicating portions of the file. Each extracted block of original file is compressed and queued for transmission to a target-receiving computer. The compressed blocks are kept in a queue, and potentially, encrypted in accordance with known encryption techniques and then transmitted asynchronously to a target receiving computer over a selected communications network, such as the Internet. Since the transmission of blocks to the receiving computer occurs asynchronously with respect to the block extraction and compression procedures, each of those also being asynchronous, overall transmission times are significantly improved. Upon receipt at the receiving computer of a particular transmitted block, blocks are decrypted and decompressed and asynchronously reassembled to reconstruct the original file. The reconstruction of the original file can either occur progressively as individual blocks are received and decompressed or, alternatively, reconstructed at once upon the reception of an end of transmission signal from the transmitting computer. Multiples of receiving computers can receive identical broadcast transmissions of file block partitions from the source transmitting computer to further improve the transmission speeds by sharing the initial block extraction process amongst a plurality of receiving computers.

Other features, objects, and advantages of the present invention will become apparent from a reading of the following description as well as a study of the appended drawings.

### BRIEF DESCRIPTION OF THE DRAWINGS

A system and method for transferring files over a communications network is depicted in the attached drawings which form a portion of the disclosure and wherein:

FIG. 1 is a Cartesian time graph showing a current typical method of compressing and transferring a file from one computer location to another in the shortest available time;

FIG. 2A is a Cartesian time graph showing the time shifting of the file transmission segment in a nominal file transfer operation to overlap and reduce overall transmission time;

FIG. 2B is another Cartesian time graph showing additional savings obtained by overlapping file decompression time with file transmission time in a file transfer strategy;

FIG. 3 is a diagrammatic view showing the transmitting environment of the invention utilizing known communications networks to transfer files from one location to a single or a plurality of targeted receiving computers;

FIG. 4 is a process flow diagram showing the primary steps for preparing and transmitting a file from a transmitting computer utilizing the invention;

FIG. 5 is a process flow diagram showing the primary steps in establishing an encryption protocol with a receiving computer from the source transmitting computer;

FIG. 6 is a process flow diagram showing the primary steps in receiving and decoding a transmitted file at the receiving computer in accordance with one embodiment of the invention;

FIG. 7 is a process flow diagram showing the primary steps in receiving and decoding a transmitted file at the receiving computer in accordance with a second embodiment of the invention; and,

FIG. 8 is an object function diagram showing the primary processes and functions of the invention.

### DESCRIPTION OF THE PREFERRED EMBODIMENTS

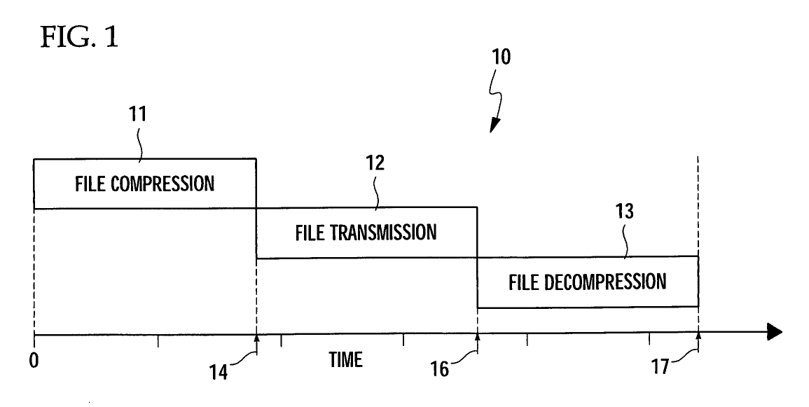

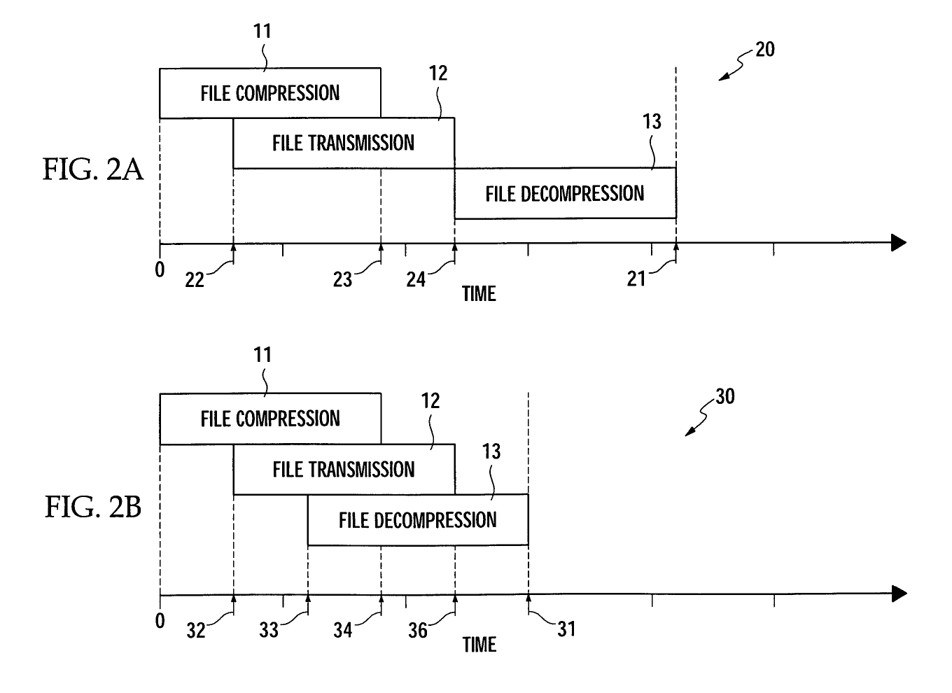

Referring to the drawings for a better understanding of the function and structure of the invention, FIGS. 2A and 2B show the general underlying theory for the herein disclosed invention. Nominal transmission strategies 10, as depicted in FIG. 1, normally gain transmission time advantages, especially in large file situations, by first compressing the file to be transmitted and then decompressing the file upon receipt at a receiving computer after transmission completion from the sending computer. Each phase of the file transmission procedure 11, 12, 13, occurs synchronously and, therefore, serially. Hence, the overall time for transmission of a file from one computer to another is dependent upon the time aggregation 17 of the required time to complete each step 11-13. Conversely, the herein described system and method utilizes asynchronous transmission phases to dramatically improve the overall file transmission performance from one computer to another.

The embodiment 20 of the invention in FIG. 2A permits time shifting of the file transmission phase 12 such that the phase 12 begins at sometime 22 less than the completion time 23 of file compression phase 11. File decompression phase 13 is unaffected in this embodiment, but the overall file transmission performance 21 is significantly reduced as compared to the nominal transmission method 10 by a time factor delineated by timesavings between points 22 and 23. Specifically, file compression phase 11 and file transmission phase 12 are merged from a time perspective to achieve a cumulative time increase above the compression phase 11 of 23-24. Therefore, the overall performance gain between total file transmission times 21 and 17 of procedures 10 and 20 is the time shifted overlap interval 22-23.

A second embodiment 30 of the herein disclosed invention achieves further file transmission performance gains as shown in FIG. 2B by overlapping both file transmission 12 and file decompression 13 phases with file compression phase 11. As shown in the embodiment 20 of FIG. 2A, the embodiment 30 of FIG. 2B achieves the same performance gains between file compression phase 11 and file transmission phase 12 by virtue of the merged time interval 32-34, but further gains are achieved by overlapping file decompression phase 13 with file transmission phase 12 to achieve an additional gain of 33-36. Hence, the overall transmission performance gain of intervals 32-34 plus 33-36 to achieve an overall file transmission performance time 31 significantly better than the overall nominal file transmission time 17. Using such an asynchronous strategy, the herein disclosed system and method can achieve performance gains of a minimum of 100-200 percent over nominal file transmission times currently utilized in the industry.

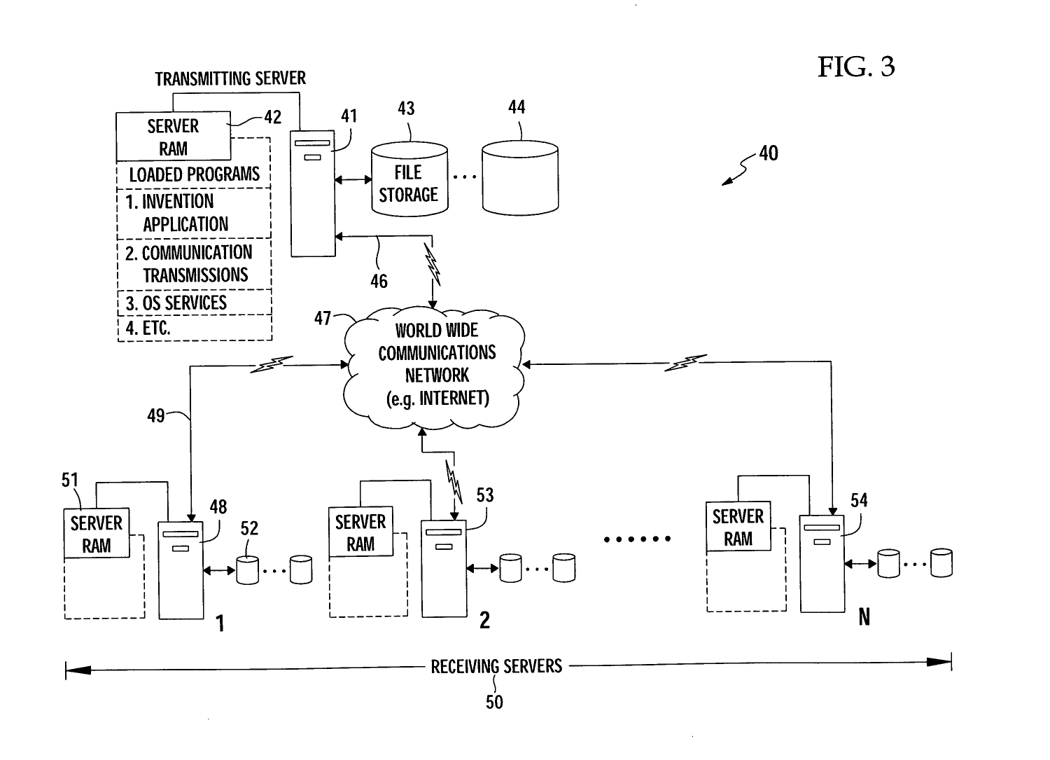

Referring to FIG. 3, one may see a typical communications environment in which the present invention would operate. A transmitting server 41 running a standard operating system, such as Windows 2000 or Windows XP, will have loaded programs in its RAM 42 providing a multiplicity of services and system extensions upon which the present invention relies. For example, the disclosed system is designed to be an OS portable application, but currently runs under Windows 2000 operating system, or later, including XP. In file transfers in which the communications medium connecting the transmitting computer with a target receiving computer utilizes the Internet, IIS 5.0+ (Internet Information Services) is initiated to: (1) supply or host a multitude of HTTP communications channels with a remote target receiving server, including supplying current communications parameters back to the invention; (2) keeping track of “receiver objects” as file transfer jobs are prepared for transmission; and (3) process each block transmission. The invention is created using the Microsoft .NET Framework which coordinates command exchanges between the Windows operating system and IIS. An SQL Server 2000 or MSDE (Microsoft Data Engine) is also utilized to record the current status of the invention (e.g. current settings), including the status of each file transmission in progress. In the event of a computer disruption, the current operation can be resumed without loss of data and transmissions automatically resumed. In as much as communications systems under Windows environments, such as 2000 and XP, are well understood and not necessary for a complete understanding of the herein described invention, further explanations of the workings and operations of the Windows platform OS and its inherent capabilities to communicate over the Internet with a target computer site will be omitted.

A transmission portion of the herein disclosed invention is loaded on computer server 41 and operates within the server ram 42 to administer the transmitting of files from transmitting server 41 to one or more receiving servers 50. File storage 43, which may or may not be scaled to associated file storage subsystems 44, interacts with transmitting server 41 to hold interim portions of transmission blocks and files in preparation for transit. Transmitting server 41 communicates over standard communication lines 46, such as, for example, dial-up, broadband, T1, T3, ISDN and other types of communication systems. It will be understood by those skilled in the art that communication conduit 46 is independent of the herein described system and method. Further, the herein described example 47 of the Internet as a medium to provide communications between a transmitting server and one or more receiving servers 50 is simply for illustration purposes and any form of communications network will operate suitably with the herein described invention, such as, Ethernet communication networks, Token Ring communication networks, optical fiber networks, radio communication based networks, microwave transmission networks, wide area networks, various other forms of proprietary local area networks, and hard wired buses.

Receiving servers 50 may be as few as one, or as many as needed to effectively broadcast a file to a preselected set of receiving computer servers. First receiving computer server 48 has loaded in its ram 51 an operating system suitable configured to communicate with remote computer systems running the operating system loaded in transmitting server RAM 42. A second portion of the herein disclosed invention is loaded in server RAM 51 to process portions of blocks received by receiving server 48 in order to effectively decrypt, decompress, and reconstitute an original file, pursuant to the herein disclosed procedures. Disk memory substances 52 as with transmitting server 41 may be locally connected to receiving server 48 or may be remotely connected via known memory subsystem communications protocols. The method by which receiving server 48 is connected to transmitting server 41, for example in this case via conduit 49 through the Internet 47, is unimportant except from the standpoint that the connecting communications network must be capable of supporting the transmission protocols utilized by the communications programs loaded in the transmitting server and receiving server RAM, which is most likely a function of services offered by a selected operating system. As will be shown, while significant gains can be achieved for file transfers between a single transmitting server and a single receiving server 50, additional gains in file transmission performance can be achieved when broadcasting a particular file to a multiplicity of receiving servers 50.

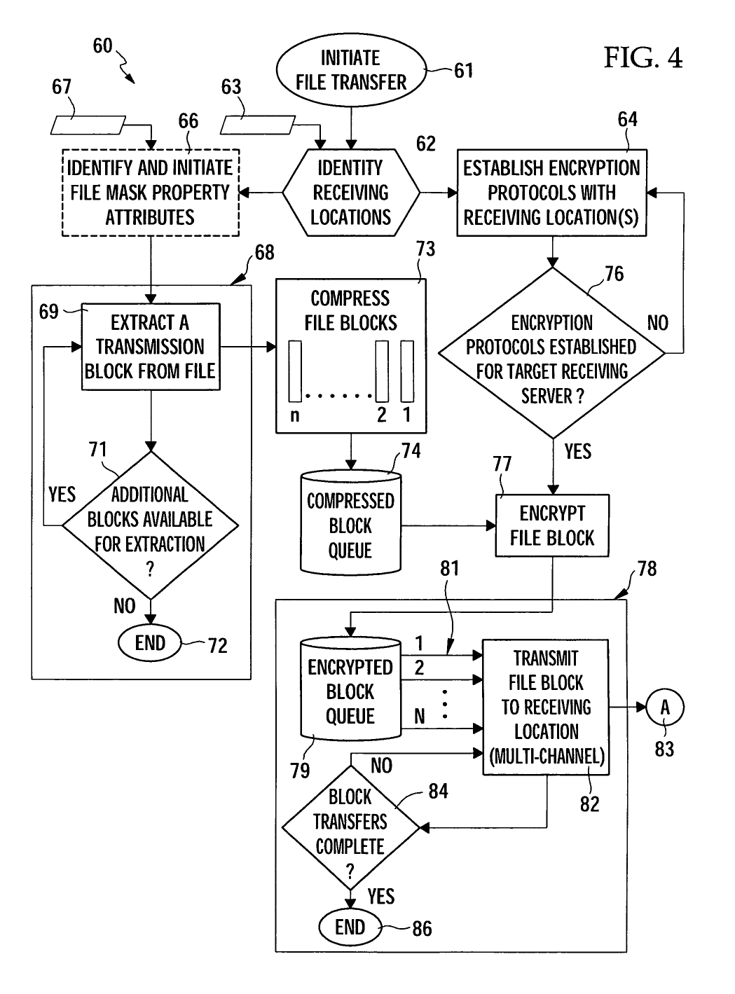

Referring now to FIG. 4, the overall process flows of the herein described invention may be seen at the transmitting server location. To initiate a file transfer 61, various types of user interfaces and/or mechanisms may be incorporated. Well-known graphical user interfaces exists for dragging and dropping files from one folder to another, in, for example, FTP applications from one computer to another computer communicating over the Internet. Hence, while certainly a command line alpha numeric command structure may be utilized to initiate a file transfer, graphical user interfaces could more likely be utilized to drag and drop files from one folder to another where one of the folders can be located on a receiving server remotely located from the transmitting server. Moreover, a particular folder or directory location could through a masking or background function 66 identify multiple locations, akin to a fax broadcast message, in which several receiving server locations are identified. Such masking 66 and data 63 can identify one or more receiving locations 62 and initiate the establishing of encryption 64 protocols for transmitting file data to a targeted receiving server location. The herein described invention can utilize both of a direct identification method and a masking identification method to initiate a file transfer and direct the transfer to a particular receiving computer or set of computers. The herein described invention may integrally combine encryption within the overall system operation, as noted above, but those skilled in the art will understand after a viewing the herein described process that both the encryption and masking sub-processes of the herein described invention are not critical to the core operation of the invention and may be removed from the overall process without affecting the overall goal of file transmission or the transmission time improvements discussed above. Once receiving locations 62 are identified and file mask properties and attributes are identified 66 for each particular file initiated for transfer, the file to be transferred is passed to a block extraction subprocess 68. An extraction routine 69 extracts a 2 MB portion of the file to be transferred and passes the extracted block to an asynchronous file compression process 73. For the purposes of this disclosure and for better clarity, a “block” is defined as an extracted sub-portion or subset portion of a file to be transmitted to the receiving computer. While a 2 MB sized block is currently utilized by the inventors and appears to be an optimal extraction size for today's file transfers utilizing today's Internet communication conduits, it is expected that the size of each extraction block will vary by system and evolve over time to accommodate various types of system configurations and communications environments. Further, the invention herein anticipates that this extraction block size could be intelligently varied to accommodate various types of preselected parameters, and/or manually configured parameters to optimize file transmission speed. If the file to be transferred is less than 2 MB, in the herein described example, then a single 2 MB block, or less, would be passed to the file compression function 73, thereby exhausting the contents of a selected file. Additional 2 MB blocks are extracted from the file asynchronously until all of the available blocks have been extracted from the file to be transferred 71. Asynchronously with the extraction operation from module 68, extracted blocks are passed to compression utility 73 and each block is asynchronously compressed in accordance with a preselected compression utility that is invoked by the transmission subsystem 60 of the herein described invention. Various types of compression utilities may be utilized in the herein describe invention and the inventors anticipate that as compression utilities improve that those compression utilities could be incorporated into the herein disclosed invention as desired. The current compression utility utilized by the inventors is referred to in the industry as “G-Zip” and allows for rapid compression and decompression asynchronously of file blocks. Compression 73 occurs on blocks serially, although asynchronously, as received from extraction subsystem 68 and each compressed block is then queued 74 in temporary storage in preparation for file encryption 77. As stated above, this encryption is not necessary for the herein described invention to operate, however, encryption is useful and desirable for most corporate communications over nonsecure networks such as the Internet.

In order for the transferring computer server to establish a proper encryption protocol with the receiving computer, a set of standard security keys must be exchanged to allow for efficient encryption and decryption of received file blocks. Normally, encryption protocols would be established with the target receiving computer 64 quite rapidly and precede the completion of file block compression by a comfortable time margin. However, should encryption be an inherent component to the system and encryption protocols have not yet been established with the target receiving server, then file block transmission could be delayed until file block encryption can proceed at step 77.

While the file transfer process depicted in FIG. 4 is the preferred embodiment, a slightly altered process flow may have advantages. As shown in the figure, the extracting of blocks in subprocess 68 is initiated before individual blocks are compressed 73, and then encrypted 77. However, while these steps are occurring asynchronously with respect to one another, the inventors also envision the overall system 60 in which either encryption and compression subprocesses might be initiated prior to the initiation of the file block extraction process. For example, an individual file might be compressed 73 after the file mask subprocess 66 completes, with block extraction and encryption occurring after file compression. Further, a file might be encrypted prior to either extraction or compression. This might provide advantages in the overall process by allowing a more definitive file transfer size to be known prior to extraction and transmission, thereby allowing better block size optimization and faster data transmission. Also, a higher level of security is provided if the extraction process is to be carried out on unsecured hardware, such as for example at a remote distributed processing location.

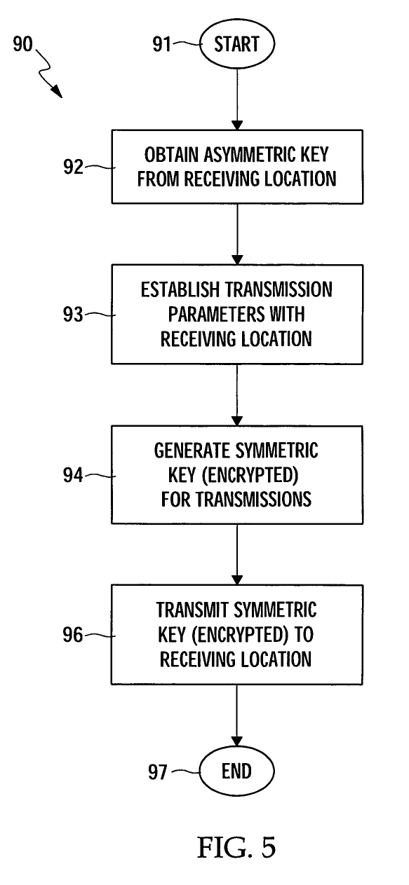

Referring now to FIG. 5 a standard establishment of encryption protocols under step 64 is further explained. Upon identification of the target receiving computer server 91, an asymmetric key is obtained from the receiving location 92 and a common security protocol for transmission parameters is established with the target receiving location 93. The transmitting computer server then generates a symmetric key for transmission 94, sometimes referred to as a “session key,” and the symmetric key is then encrypted utilizing the public asymmetric key obtained from the target receiving location. The encrypted symmetric key is then transmitted 96 to the target computer receiving location to enable rapid decryption of any received file blocks at the receiving computer server in accordance with the established security transmission parameters. Once the encrypted symmetric key is transmitted to the receiving location, step 64 would be complete and encryption of file blocks 77 can proceed asynchronously with respect to both the extraction subsystem 68 and the compression sub-process 73. The encryption protocols established in step 64 are well-known standard security structures utilizing symmetric and asymmetric, public-private key exchanges, as are utilized in SSL and SHTTP communications. Various types of public-private key encryption algorithms exists and may be utilized in the herein invention. For example, RSA (Rivst Shamir Adleman) and ECDSA (a variant of DSA) may be utilized. Also, while the herein disclosed invention currently utilizes RC5 for symmetric encryption of the blocks transmitted, other types of symmetric encryption schemes may be utilized such as DES (Data Encryption Standard) or AES. Some symmetric key algorithms also require an initialization vector that may be supplied, in encrypted form, to a target receiving computer. Therefore, once the encryption protocols have been established 76, each file block queued 74 may be then encrypted 77 and passed to another queue 79 awaiting asynchronous transmission to a target computer receiving location.

Referring again to FIG. 4, it may be seen that multiple threads or channels are available to pass encrypted blocks from queue 79 to a transmission subprocess 82 to transfer blocks to target receiving computers 83. While encrypted blocks are queued in first-in-first-out (FIFO) format from encryption function 77, transmission subsystem 82 allows any available channel to obtain any available encrypted block in parallel 81 so that multiple simultaneous channels (e.g. 10) may continually transmit blocks to one or more target receiving server computers. Inventors have experienced some incremental performance increases by allowing multiple channels or multiple transmission threads to operate. As is shown, the order of transmission of any particular block is unimportant for the overall successful operation of the herein described invention since blocks are reassembled at their respective destinations in accordance with a final block naming convention, as will be described. Therefore, the order of transmittal of a particular block can proceed asynchronously and out of order with respect to any other process at the transmitting computer server.

In order to keep track of each file block being transferred within system 40, a file name convention has been established. Prior to block extraction subprocess 68, and preferably during step 66, the file to be transferred is renamed to annotate the suffix with an arbitrary time stamp string such as, for example, in the following:

TABLE 1

```
Starting file name: myfile.txt
New File Name: myfile_200304010908599512.txt
Where “200304010908599512” = yyyyMMddhhmmssffff as in:
  yyyy = year
  MM = month
  dd = day
  hh = hour
  mm = minute
  ss = second
  ffff = millisecond
```

Thereafter, each extracted file block adopts the file name convention identical to the initially applied name convention, but adds a period and a file block number within a five digit sequence as shown below:

myfile_{—}200304010908599512.txt.F0000

myfile_{—}200304010908599512.txt.F0001

myfile_{—}200304010908599512.txt.F0002

.

.

.

myfile_{—}200304010908599512.txt.F000n

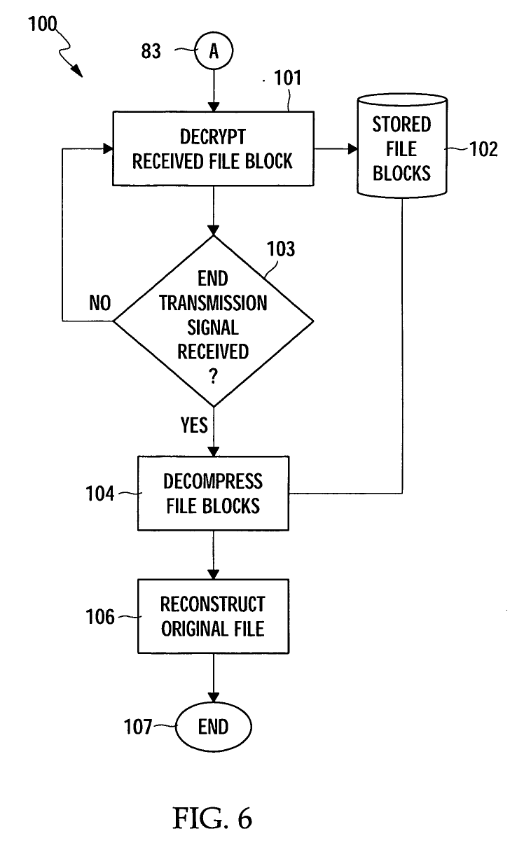

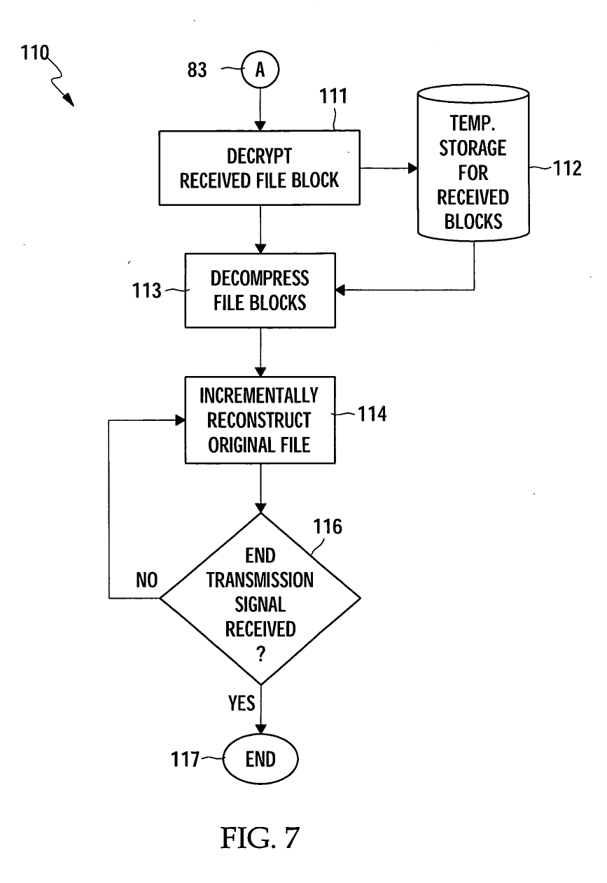

The reconstruction component of the herein described invention loaded on the target receiving computer server is, therefore, able to identify each received block in is accordance with this naming convention and reassemble blocks in their proper sequence to recreate the original file as will be described further in FIGS. 6 and 7.

As each block is transmitted to target receiving locations 82, the transmission subsystem 78 checks to see if all blocks for a particular file have been transferred 84. If all blocks have been transferred successfully, the transmission subprocess 78 ends 86. Alternatively, transmission file block process 82 continues until all blocks are sent. Once the transmission subsystem 78 has finished transmitting all of the file blocks and the subprocess ends 86, an end transmission signal is transmitted to the target receiving computer server 83.

Referring now to FIGS. 6 and 7, a transmitted block 83 is received by target receiving computer server, decrypted 101, and stored in a file block memory location 102 for further processing. The receiving computer server continually looks for an end of transmission signal 103 and continues to decrypt file blocks until such a signal is received. Once the end of transmission signal is received, all of the stored file blocks 102 are decompressed 104 and reconstructed 106 into the original file utilizing the above described file block naming convention to properly order each block. Once the original file is reconstructed 106, recreation process 100 is ended 107 and the original file may be then moved to a preselected location pursuant to other user interface commands which may have been passed to the target receiving computer's management control portion of the herein described invention.

As shown in FIG. 7, another embodiment 110 of the herein described enclosed invention 110 is shown in which incremental reconstruction of the original file proceeds to obtain asynchronous progression of transmission and decompression phases of the herein described invention pursuant to the model 30 shown in FIG. 2A. Specifically, each received block is decrypted 111 and passed to a temporary storage location 112 for each decrypted file block. Asynchronously with regard to an encryption process 111, each file block is decompressed 113 as available from temporary storage location 112 and a dummy file is created by the system and filled with zeros to match the size of the original file. As each file block is decompressed 113, the system is knowledgeable as to its proper location within the dummy file stored on the receiving computer system. As each file block is decompressed, it is incrementally appended into the original file by overwriting an existing portion of the dummy file precreated by the process 110. The location onto which a particular file block is overwritten can be calculated since the size of each file block is pre-selected in the block extraction process, remaining consistent throughout the operation of the process, and the order relative to other blocks is established in the file suffix naming convention. The system continually checks for an end of transmission signal 116 and upon receipt of such a signal passes the reconstructed original file to an invention management program to save the original file in a preselected location dictated by properties controlled in step 66. By incrementally reconstructing the original file in an asynchronous manner, additional transmission performance gains can be realized pursuant to the discussion above in FIGS. 2A and 2B.

While the inventors of the herein disclosed invention utilize a file suffix naming convention to govern the reconstruction of transmitted file blocks, other strategies are perfectly acceptable. For example, a separate transmission might be sent along with each block transmission to indicate its order relative to the other blocks, or each block transmission might include in its data stream an identifying portion that can be reclaimed at the receiving computer to indicate the blocks order relative to other received blocks. In fact, any identifying data that can be properly associated with a specific block transmission can be utilized to indicate to the file reconstruction sub-function its proper place in the asynchronously received group of blocks. Such ordering data indicia can even be based upon an inherent property of the transmitted block or be encoded within the block data itself. For the purposes of this disclosure, the term “ordering data indicia” is hereby defined as any purposeful data designed to provide information on the ordering relationship of the transmitted blocks to allow faithful reconstruction of the original file contents at the receiving computer.

Regardless of which reception and reconstruction method is utilized 100 or 110, transmission and reception of identical blocks at a plurality of receiving computers will improve realized transmission performance. Portions of transmission process 60 need execute only one time for a set of receiving computers, thereby allowing for a distribution of part of the process time for the operational steps shown in 60 over the range of receiving computers. While some additional transmission time in step 82 and some additional time may be required to establish security protocols, the time required to complete steps 61, 66, 68, 73, and 77, can be shared by all receiving computers. Therefore, each receiving computer will experience real overall transmission times reductions for any file broadcast to a multiplicity of receiving computers.

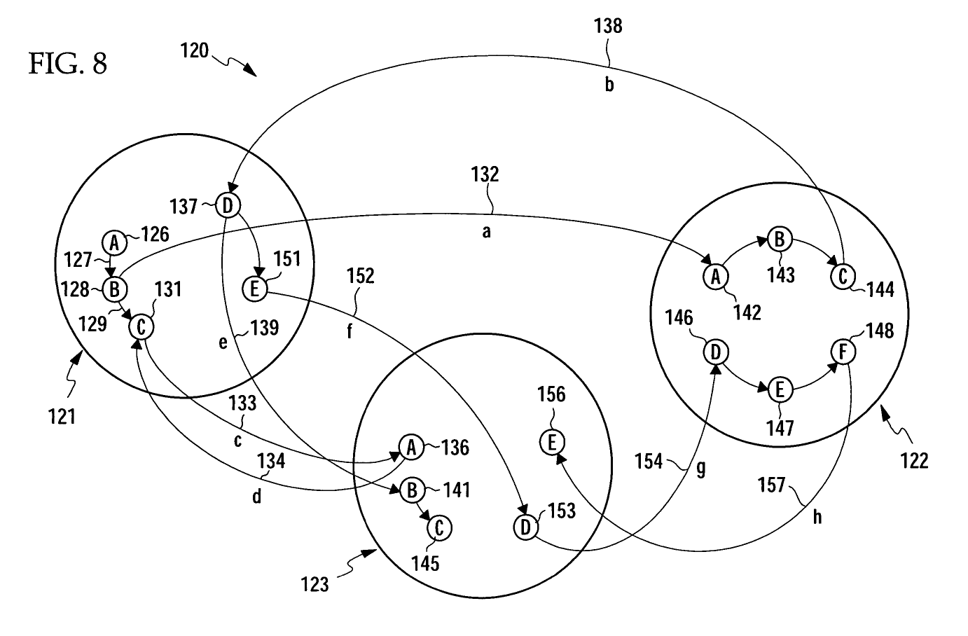

FIG. 8 shows the system object structure for the apparatus components 120 of the disclosed invention. A sender module 121 running on a transmitting computer server controls and initiates transmissions to a receiver module 123 running on a target receiving system. A compression manager module 122 combines a number of sub-processes, some running on the target receiving system and some running on the transmitting computer server, for controlling the compression and decompression of transmitted file blocks.

Sender module 121 includes a sub-function 126 that creates a transmission data set 127 for holding the state of any particular transmission job and for re-instituting an interrupted transmission job. Sub-function 128 examines file attributes of the file selected for transmission to determine if existing predefined rules automatically identify target receiving locations to which the file should be transmitted. The file name and location is passed 132 by the file attribute sub-function 128 to the compression manager module 122 for further segmentation and compression processing of the file. Any identified target receiving locations 129 are passed to a transmission initiator 131 that retrieves asymmetric key information from the target receiving location(s) and generates the proper symmetric keys for use during file transmission. These keys govern the encryption and decryption sub-functions in the sender and receiver modules 121, 123 during block transmissions. Encryption information 133-134 is exchanged with the receiver module 123 via receiver sub-function 136 residing on all of the target receiving computers. An encryption sub-function 137 in sender module 121 utilizes the public key retrieved by sub-function 131 to encrypt any blocks 138 compressed in sub-module 122 and to transmit the compressed, encrypted blocks 139 to a target receiving computer sub-function 141.

Compression manager sub-module 122 includes mirror sub-functions running on the transmitting server 142-144 and running on the target receiving computer 146-148. Sub-function 142 initiates a compression process by allocating memory to use as a buffer for the compression and instantiating a compression manager to manage the implementation of the G-Zip compression algorithms. Sub-function 143 extracts a 2 Mb file section from the identified file 132 and compresses it. Another sub-function 144 temporarily stores the extracted compressed file section in a temporary folder and coordinates with sub-function 137 for transmission of the block to the target receiving computer.

A transmission completion sub-function 151 monitors the transmission process in coordination with sub-function 137 and upon transmission completion of all of the compressed, encrypted blocks to a targeted receiving computer sends an end of transmission signal 152 to sub-function 153 in receiver module 123. The sub-function 141 decrypts any received blocks and temporarily stores each decrypted block via sub-function 145. The receiver end of transmission sub-function 153 controls 154 resident sub-function 146 to initiate the decompression of one or all of the received blocks. Sub-function 147 decompresses one or all of the received blocks and reconstruction sub-function 148 orders and appends the decompressed blocks to reconstruct the original file. Once all of the blocks have been reconstructed into the original file, file handler sub-function 156 accesses the reconstructed file 157 and stores it in a pre-designated location on the target receiving computer.

One of the difficulties in coding the disclosed invention pertains to the asynchronous execution of various of the above identified modules and sub-functions, as well as others. Asynchronous execution of sub-processes relies upon the ability to spawn multiple threads and attach them to different functions and processes. Below are listed some example processes that are asynchronous in the disclosed invention:
File Status Monitoring
Block Compression
File Splitting (i.e. segmentation)
Communications Authentication
Transmission Initiation
File Block Transmission
Sending an End of Transmission Signal
File Reconstruction
File Storing

One of the problems encountered in the design of the herein described system is that available threads in any particular thread pool for a particular invoked application are exhausted quickly, thereby causing processing deadlocks during execution. The deadlocks occur due to the processes, along with the underlying .NET framework, exhausting all the threads in the available thread pool. Obviously, the inventors had no wish to limit the number of threads available for any running module or sub-function to allow for the most efficient processing of files. This was solved by implementing a queued based system based upon an asynchronous timer. The timer is used to check various queues within the system based on a known time interval. For example, a selected system timer governs when to check for any available file blocks that are awaiting compression. Every 50 milliseconds the system spawns an asynchronous thread that checks the compression queue. If a message is found in the queue, it is popped and processed asynchronously utilizing the same thread generated from the timer function. An asynchronous queued timer system allows for easy configuration and management of executing process threads. In this manner, the number of executing threads in process at any instant can be monitored and controlled through a shared member. For example, the transmission sub-function 137 can be limited to ten simultaneous file transmissions.

Such an asynchronous queuing system adds to the fault tolerance of the invention. For example, if a transmission process initiated from the top of the queue fails due to, say, a network error, the same failed process can be placed at the bottom of the queue for re-initiation.

Another challenge faced in the asynchronous multi-threading environment of the present invention is synchronization. Many objects in the .NET framework are, or are easily made, “thread-safe.” That is, a synchronized queue object handles both reading and writing of data and ensures that the same memory is not accessed by two different threads simultaneously. The “queue object” used in the system is an example of such a sub-process. Some objects, for example “Data-Sets,” which are used to maintain state throughout a file transmission are not thread-safe, which can lead to random timing issues arising with regard to threading and datasets. This can be remedied, by using the .NET SyncLock capabilities where are part of the .NET command set. A “Sync-Lock Block” command can be assigned to a particular process to ensure that code inside the process is not executed by more that one process thread simultaneously. In this manner, variously executed asynchronous processes can be sync-locked to avoid problems in asynchronous thread executions.

While I have shown my invention in one form, it will be obvious to those skilled in the art that it is not so limited but is susceptible of various changes and modifications without departing from the spirit thereof.

Having set forth the nature of the present invention, what is claimed is:

1. A method for efficiently transferring files from a transmitting computer to a receiving computer, comprising the steps of:
a. identifying an original file for transmission;
b. compressing said file identified in said identifying step;
c. upon the availability of any compressed portion of said file, asynchronously extracting one or more blocks from said compressed portion until said file has been fully extracted into said one or more compressed blocks, each said block containing an exact copy of a portion of said compressed original file, and wherein each said block has a predetermined size;
d. transmitting each said compressed block and ordering data indicia over a communications network to said receiving computer, said transmitting step occurring asynchronously with regarding to said extraction step;
e. decompressing each said transmitted block at said receiving computer; and,
f. reconstructing said original file from said decompressed blocks.

2. A method as recited in claim 1, wherein said method includes a step to establish an encryption protocol between said transmitting computer and said receiving computer, and wherein each block is encrypted prior to said transmitting step and decrypted at said receiving computer prior to said reconstruction step.

3. A method as recited in claim 2, wherein said transmitting step utilizes a plurality of channels to asynchronously transmit said compressed blocks in parallel.

4. A method as recited in claim 3, wherein said extraction step comprises, calculating the size of said compressed file, copying a portion of data from said compressed file in sequence equal to a predetermined block size, applying a naming convention to said extracted block to serve as said ordering data indicia of its representative position within said original file, and continuing to extract blocks sequentially relative to the data held by said compressed file until said compressed file is completely extracted.

5. A method as recited in claim 4, wherein said transmitting computer sends an end transmission signal to said receiving computer to signify completion of transmission of all blocks pertaining to said original file and said reconstruction step initiates in response thereof.

6. A method as recited in claim 5, wherein said transmitting step comprises transmitting said block to a plurality of discrete receiving computers.

7. A method as recited in claim 1, wherein said transmitting step utilizes a plurality of channels to asynchronously transmit said compressed blocks in parallel.

8. A method as recited in claim 7, wherein said extraction step comprises, calculating the size of said compressed file, copying a portion of data from said compressed file in sequence equal to a predetermined block size, applying a naming convention to said extracted block to serve as said ordering data indicia of its representative position within said original file, and continuing to extract blocks sequentially relative to the data held by said compressed file until said file is completely extracted.

9. A method as recited in claim 8, wherein said transmitting computer sends an end transmission signal to said receiving computer to signify completion of transmission of all blocks pertaining to said original file and said reconstruction step initiates in response thereof.

10. A method as recited in claim 9, wherein said transmitting step comprises transmitting said block to a plurality of discrete receiving computers.

11. A method as recited in claim 1, wherein said reconstructing step proceeds concurrently with said decompressing step such that the total time to decompress all received blocks and reconstruct said original file is less that the sum of time for all decompression and reconstruction steps.

12. A method as recited in claim 11, wherein said method includes a step to establish an encryption protocol with said receiving computer and wherein each block is encrypted prior to said transmitting step and decrypted at said receiving computer.

13. A method as recited in claim 12, wherein said reconstructing step includes the pre-creation of a dummy file into which received blocks are appended at their respective sequences within said original file.

14. A method as recited in claim 13, wherein said transmitting step utilizes a plurality of channels to asynchronously transmit said compressed blocks simultaneously.

15. A method as recited in claim 14, wherein said extraction step comprises, calculating the size of said compressed file, copying a portion of data from said file in sequence equal to a predetermined block size, applying a naming convention to said extracted block to serve as said ordering data indicia of its representative position within said original file, and continuing to extract blocks sequentially relative to data held by said compressed file until said file is completely extracted.

16. A method as recited in claim 1, wherein said method includes a step to establish an encryption protocol with said receiving computer and wherein each block is encrypted prior to said extraction step and decrypted at said receiving computer.

17. A method as recited in claim 16, wherein said transmitting step utilizes a plurality of channels to asynchronously transmit said blocks simultaneously.

18. A method as recited in claim 1, wherein said reconstructing step occurs after decompressing all blocks received from said transmitting computer.

19. A method as recited in claim 1, wherein said decompression step occurs after said reconstruction step.

20. A method for efficiently transferring files from a transmitting computer to a receiving computer, comprising the steps of:
a. identifying an original file for transmission;
b. compressing said original file;
c. extracting a block from said compressed original file to replicate a portion of said compressed original file data;
d. transmitting said compressed block and ordering data indicia to said receiving computer;
e. iteratively and asynchronously repeating steps b-d until all of said original file has been compressed and fully extracted into blocks, and each compressed block transmitted to said receiving computer;
f. iteratively decompressing each received compressed block at said receiving computer until all blocks representing said original file have been decompressed; and,
g. reconstructing said original file from said decompressed blocks.

21. A method as recited in claim 20, further including a step to establish an encryption protocol with said receiving computer and encrypt said original file prior to said extraction step.

22. A method as recited in claim 21, wherein said reconstructing step occurs after decompressing all blocks received from said transmitting computer.

23. A method as recited in claim 22, wherein said extraction step comprises, calculating the size of said compressed file, copying a portion of data from said compressed file in sequence equal to a predetermined block size, applying a naming convention to said extracted block to serve as said ordering data indicia of its representative position within said original file, and continuing to extract blocks sequentially relative to the data held by said compressed file until said file is completely extracted.

24. A method as recited in claim 23, wherein said transmitting step utilizes a plurality of channels to transmit said compressed blocks in parallel.

25. A method as recited in claim 24, wherein said reconstructing step proceeds concurrently with said decompressing step such that the total time to decompress all received blocks and reconstruct said original file is less that the sum of time for all decompression and reconstruction steps.

26. A method as recited in claim 25 wherein said reconstructing step includes the pre-creation of a dummy file into which decompressed blocks are appended in sequence until said original file is reconstructed.

27. A method as recited in claim 26, wherein said transmitting step utilizes a plurality of channels to transmit said compressed blocks in parallel.
